(19) United States
(12) Patent Application Publication
(10) Pub. No.: US 2026/0005650 A1
(43) Pub. Date: Jan. 1, 2026

(54) METHODS AND APPARATUS TO COMPENSATE FOR PACKAGE STRESS VARIANCE OR TEMPERATURE VARIANCE

(71) Applicant: Texas Instruments Incorporated, Dallas, TX (US)

(72) Inventors: Nitin Agarwal, Bengaluru (IN); Nikhil Das, Bengaluru (IN)

(21) Appl. No.: 18/758,650

(22) Filed: Jun. 28, 2024

(51) Int. Cl. H03B 5/24

(52) U.S. Cl. CPC H03B 5/24

(57) ABSTRACT

An example apparatus includes a first resistor including a first terminal coupled to a first output terminal of a current mirror and a second terminal coupled to a ground terminal. The apparatus includes a first switch including a first terminal coupled to a second output terminal of the current mirror, a capacitor including a first terminal coupled to a second terminal of the first switch, and a second resistor including a first terminal coupled to a second terminal of the capacitor and a second terminal coupled to the ground terminal. The apparatus includes a second switch including a first terminal coupled to the first terminal of the capacitor and a second terminal coupled to the ground terminal, a third switch including a first terminal coupled to the first terminal of the capacitor, and a comparator including an input terminal coupled to a second terminal of the third switch.

### TECHNICAL FIELD

This description relates generally to electronic circuits and, more particularly, to methods and apparatus to compensate for package stress variance or temperature variance.

### BACKGROUND

A resistor is a passive electrical component having at least two terminals. A resistor implements an electrical resistance as an element in a circuit to reduce current flow, adjust a signal voltage, divide a voltage, bias an active element of the circuit, or terminate a transmission line, among other uses. A resistor may have a fixed resistance or a variable resistance. A resistor having a variable resistance can be used to adjust operation of a circuit or as a sensing device. A resistor may be implemented as a discrete component or within an integrated circuit.

### SUMMARY

For methods and apparatus to compensate for package stress variance or temperature variance, an example apparatus includes a current mirror including a first output terminal and a second output terminal. The apparatus includes a first resistor including a first terminal coupled to the first output terminal of the current mirror and a second terminal coupled to a ground terminal. The apparatus includes a first switch including a control terminal, a first terminal, and a second terminal, the first terminal of the first switch coupled to the second output terminal of the current mirror. The apparatus includes a capacitor including a first terminal and a second terminal, the first terminal of the capacitor coupled to the second terminal of the first switch. The apparatus includes a second resistor including a first terminal coupled to the second terminal of the capacitor and a second terminal coupled to the ground terminal. The apparatus includes a second switch including a control terminal, a first terminal, and a second terminal, the first terminal of the second switch coupled to the first terminal of the capacitor, the second terminal of the second switch coupled to the ground terminal. The apparatus includes a third switch including a control terminal, a first terminal, and a second terminal, the first terminal of the third switch coupled to the first terminal of the capacitor. The apparatus includes a comparator including an input terminal and an output terminal, the input terminal of the comparator coupled to the second terminal of the third switch. The apparatus includes frequency generation circuitry including an input terminal coupled to the output terminal of the comparator, a first output terminal coupled to the control terminal of the first switch and the control terminal of the third switch, and a second output terminal coupled to the control terminal of the second switch. Other examples are described.

For methods and apparatus to compensate for package stress variance or temperature variance, an example apparatus includes a current mirror including a first output terminal and a second output terminal. The apparatus includes a first resistor including a first terminal and a second terminal, the first terminal of the first resistor coupled to the first output terminal of the current mirror. The apparatus includes a second resistor including a first terminal coupled to the second terminal of the first resistor and a second terminal coupled to a ground terminal. The apparatus includes a first switch including a control terminal, a first terminal, and a second terminal, the first terminal of the first switch coupled to the second output terminal of the current mirror. The apparatus includes a capacitor including a first terminal and a second terminal, the first terminal of the capacitor coupled to the second terminal of the first switch. The apparatus includes a third resistor including a first terminal coupled to the second terminal of the capacitor and a second terminal coupled to the ground terminal. The apparatus includes a second switch including a control terminal, a first terminal, and a second terminal, the first terminal of the second switch coupled to the first terminal of the capacitor, the second terminal of the second switch coupled to the ground terminal. The apparatus includes a third switch including a control terminal, a first terminal, and a second terminal, the first terminal of the third switch coupled to the first terminal of the capacitor. The apparatus includes a comparator including an input terminal and an output terminal, the input terminal of the comparator coupled to the second terminal of the third switch. The apparatus includes frequency generation circuitry including an input terminal coupled to the output terminal of the comparator, a first output terminal coupled to the control terminal of the first switch and the control terminal of the third switch, and a second output terminal coupled to the control terminal of the second switch. Other examples are described.

For methods and apparatus to compensate for package stress variance or temperature variance, an example apparatus includes a current mirror including a first output terminal and a second output terminal. The apparatus includes a first resistor including a first terminal and a second terminal, the first terminal of the first resistor coupled to the first output terminal of the current mirror. The apparatus includes a second resistor including a first terminal coupled to the second terminal of the first resistor and a second terminal coupled to a ground terminal. The apparatus includes a first switch including a control terminal, a first terminal, and a second terminal, the first terminal of the first switch coupled to the second output terminal of the current mirror. The apparatus includes a first capacitor including a first terminal and a second terminal, the first terminal of the first capacitor coupled to the second terminal of the first switch. The apparatus includes a third resistor including a first terminal and a second terminal, the first terminal of the third resistor coupled to the second terminal of the first capacitor. The apparatus includes a fourth resistor including a first terminal coupled to the second terminal of the second resistor and a second terminal coupled to the ground terminal. The apparatus includes a second switch including a control terminal, a first terminal, and a second terminal, the first terminal of the second switch coupled to the first terminal of the first capacitor, the second terminal of the second switch coupled to the ground terminal. The apparatus includes a third switch including a control terminal, a first terminal, and a second terminal, the first terminal of the third switch coupled to the first terminal of the first capacitor. The apparatus includes a fourth switch including a control terminal, a first terminal, and a second terminal, the first terminal of the fourth switch coupled to the second output terminal of the current mirror. The apparatus includes a second capacitor including a first terminal and a second terminal, the first terminal of the second capacitor coupled to the second terminal of the fourth switch. The apparatus includes a fifth resistor including a first terminal and a second terminal, the first terminal of the fifth resistor coupled to the second terminal of the second capacitor. The apparatus includes a sixth resistor including a first terminal coupled to the second terminal of the fifth resistor and a second terminal coupled to the ground terminal. The apparatus includes a fifth switch including a control terminal, a first terminal, and a second terminal, the first terminal of the fifth switch coupled to the first terminal of the second capacitor, the second terminal of the fifth switch coupled to the ground terminal. The apparatus includes a sixth switch including a control terminal, a first terminal, and a second terminal, the first terminal of the sixth switch coupled to the first terminal of the second capacitor. The apparatus includes a comparator including an input terminal and an output terminal, the input terminal of the comparator coupled to the second terminal of the third switch and the second terminal of the sixth switch. The apparatus includes frequency generation circuitry including: an input terminal coupled to the output terminal of the comparator; a first output terminal coupled to the control terminal of the first switch the control terminal of the third switch, and the control terminal of fifth switch; and a second output terminal coupled to the control terminal of the second switch, the control terminal of the fourth switch, and the control terminal of the sixth switch. Other examples are described.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a schematic diagram of an example oscillator that compensates for variation resulting from at least one electrical characteristic, according to an embodiment of the present disclosure;

FIG. 2 is a schematic diagram of an example implementation of a transmission gate, which can be utilized to implement at least one of the first switch, the second switch, the third switch, the fourth switch, the fifth switch, or the sixth switch of FIG. 1;

FIG. 3 is a schematic diagram of an example implementation of the first resistor of FIG. 1 to compensate for lateral and longitudinal package stress, according to an embodiment of the present disclosure;

FIG. 4 is a schematic diagram of an example oscillator that compensates for variation resulting from at least two electrical characteristics, according to an embodiment of the present disclosure; and

FIG. 5 is a schematic diagram of an example oscillator that compensates for variation resulting from at least three electrical characteristics, according to an embodiment of the present disclosure.

Corresponding numerals and symbols in different figures generally refer to corresponding parts unless otherwise indicated. The figures are drawn to clearly illustrate the relevant aspects of the preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates the various specific details to provide an in-depth understanding of several example embodiments according to the description. The embodiments may be obtained without one or more of the specific details, or with other methods, components, materials, and the like. In other cases, known structures, materials, or operations are not shown or described in detail so as not to obscure the different aspects of the embodiments. References to “an embodiment” in this description indicate that a particular configuration, structure, or feature described in relation to the embodiment is included in at least one embodiment. Consequently, phrases such as “in one embodiment” that may appear at different points of the present description do not necessarily refer exactly to the same embodiment. Furthermore, specific formations, structures, or features may be combined in any appropriate manner in one or more embodiments.

The resistance of a resistor depends on the size of, shape of, and material from which the resistor is made. For example, the resistance of a cylindrical resistor can be computed based on Equation 1 below. In Equation 1, ρ represents the resistivity of the material from which a cylindrical resistor is made, measured in Ohm meters (Ωm). For example, resistivity is a measure of the ability of a material to oppose electric current. In Equation 1, L represents the length of the cylindrical resistor, measured in meters (m). Also, in Equation 1, A represented the cross-sectional area of the cylindrical resistor, measured in m².

$$R = ρ \frac{L}{A} \qquad Equation 1$$

The resistivity of a material is dependent on the temperature of the material. For example, for relatively small changes in temperature (e.g., ≤100 degrees Celsius (° C.)), the change in resistivity can be computed based on Equation 2 below. For relatively large changes in temperature (e.g., >100° C.), the change in resistivity of a material may vary or be non-linear. In Equation 2, ρ represents the resistivity of a material, measured in Ωm, after a temperature change of ΔT, measured in ° C. Also, in Equation 2, ρ₀ represents an initial resistivity of the material at an initial temperature, usually room temperature (e.g., about 20° C.). In Equation 2, α represents a first-order temperature coefficient of resistivity for the material, measured in parts per million (ppm) per degree Celsius (ppm/° C.), and β represents a second-order temperature coefficient of resistivity for the material, measured in ppm/° C.².

$$ρ = {ρ}_{0} ( 1 + α Δ T + β Δ {T}^{2} ) \qquad Equation 2$$

The resistance of a material is proportional to the resistivity of the material. Thus, the resistance of the material is also dependent on the temperature of the material. For example, assuming the length and cross-sectional area of a cylindrical resistor do not change over a relatively small change in temperature (e.g., ≤100° C.), the resistance of the cylindrical resistor can be computed based on Equation 3 below. In Equation 3, R represents the resistance of a material, measured in Ω, after a temperature change of ΔT, measured in ° C. Also, in Equation 3, R₀ represents an initial resistance of the material at an initial temperature, usually room temperature (e.g., about 20° C.). In Equation 3, α represents a first-order temperature coefficient of resistivity for the material, measured in ppm/° C., and β represents a second-order temperature coefficient of resistivity for the material, measured in ppm/° C.².

$$R = {R}_{0} ( 1 + α Δ T + β Δ {T}^{2} ) \qquad Equation 3$$

A resistor may also be subjected to mechanical forces. For example, a resistor can be subjected to stress when a force is applied axially across the resistor (e.g., by stretching or squeezing the resistor). By applying a force axially across a resistor, at least one of the length or the cross-sectional area of the resistor may change. As such, as a resistor is subjected to a stress, the resistance of the resistor can change according to Equation 1. When a resistor is implemented in an integrated circuit (IC) and a stress is applied to a package of the IC, the resistor is also subjected to the stress.

For an axially applied stress, strain is measured as the ratio of the change in length of a material compared to an initial length of the material when the material is subjected to a stress. For example, as the strain on a resistor increases, the length of the resistor increases, and the cross-sectional area of the resistor decreases because the resistor stretches and becomes narrower. Thus, as the strain on a resistor increases, the resistance of the resistor increases. In some examples, as the strain on a resistor increases, the resistivity of the resistor increases, which further increases the resistance of the resistor.

As illustrated in Equations 1-3, the resistivity of a material can change based on the temperature of the material. The resistivity of a material can also change as the material is subjected to stress. Therefore, if the operation of a circuit depends on the resistance of a resistor of the circuit, then the operation of the circuit may vary depending on at least one of the temperature of the resistor or the stress on the resistor. Some devices take advantage of these characteristics of resistance. For example, some electrical thermometers utilize a change in resistance of a resistor to measure temperature. Also, for example, strain gauges utilize a change in resistance of a resistor to measure strain.

Conversely, variability of device operation with respect to temperature and strain can prohibit the use of a device in certain applications. For example, some industrial and automotive applications have very stringent requirements for the operation of electrical circuits. Accordingly, if a device is to be utilized in an industrial or automotive application, such applications may require the operation of the device to be relatively invariable (e.g., with <1% variance in operation across process, voltage, and temperature (PVT) variations). Thus, if a device is to be utilized in an industrial or automotive application, such applications may require the operation of the device to be relatively invariable with respect to temperature and stress.

The operation of some components of an IC depends on the resistance of a resistor. For example, the frequency of an oscillator of an IC depends on the resistance of a resistor of the oscillator. One approach to achieve relatively low sensitivity to stress in the frequency of an oscillator is to utilize a stress sensor and, based on the measured stress on the resistor, adjust a trim code for the oscillator to compensate for the change in resistance and hold the frequency of the oscillator constant. For example, this approach utilizes an analog front end (AFE) to measure stress based on a circuit element having a known stress sensitivity. Also, this approach converts the output of the AFE to a digital value using an analog to digital converter (ADC). Based on the measured stress, this approach digitally applies a stress correction to the resistor of the oscillator to compensate for changes in the resistance resulting from package stress. However, this approach consumes a relatively large amount of area on a semiconductor die (e.g., due to at least the AFE and the ADC). Also, by adding more components to the oscillator, this approach increases potential sources of error in the oscillator.

Another approach to achieve relatively low sensitivity to stress in the frequency of an oscillator is to cancel out the strain response of a resistor of the oscillator. For example, this approach utilizes two resistors having similar strain sensitivities and subtracts the current flowing through the two resistors to set a supply current for the oscillator. However, this approach utilizes two amplifiers to perform the current subtraction. As such, this approach consumes a relatively large amount of area on a semiconductor die (e.g., due to at least the two amplifiers). Also, by adding more components to the oscillator, this approach increases potential sources of error in the oscillator.

Another approach that can achieve relatively low sensitivity to temperature and stress in the frequency of an oscillator is to implement two or more trim operations on the oscillator. For example, a first trim operation is conducted to trim a resistance of a resistor of the oscillator before packaging of the oscillator in an IC to compensate for frequency shift due to resistor variation caused by sensitivity to temperature. Also, for example, a second trim operation is conducted after packaging to trim the resistance of the resistor to compensate for sensitivity to package stress. However, this approach increases the monetary cost of an IC. For example, to trim an IC after packaging, test hardware of the IC must be accessible for an external device or person to trim the IC. This accessibility and the performance of trimming post-packaging increases the monetary cost of an IC.

Examples described herein include a circuit having an effective stress sensitivity that is within a threshold of a target value (e.g., zero). Also, examples described herein include a circuit having an effective temperature coefficient of resistivity that is within a threshold of a target value (e.g., zero). Described examples linearly combine resistors having different stress sensitivities and different temperature coefficients of resistivity with weighted ratios to achieve an effective stress sensitivity and an effective temperature coefficient of resistivity that is within a threshold of a target value (e.g., zero). Example weighted ratios include finite values such that the linear combination of resistors can be implemented on a semiconductor die.

In examples described herein, by utilizing multiple resistors having different sensitivities to stress, examples described herein achieve an effective stress sensitivity that is within a threshold of a target value (e.g., zero). Also, by utilizing multiple resistors having different temperature coefficients of resistivity, examples described herein may advantageously achieve an effective temperature coefficient of resistivity that is within a threshold of a target value (e.g., zero). As such, examples described herein consume a relatively small amount of area on a semiconductor die.

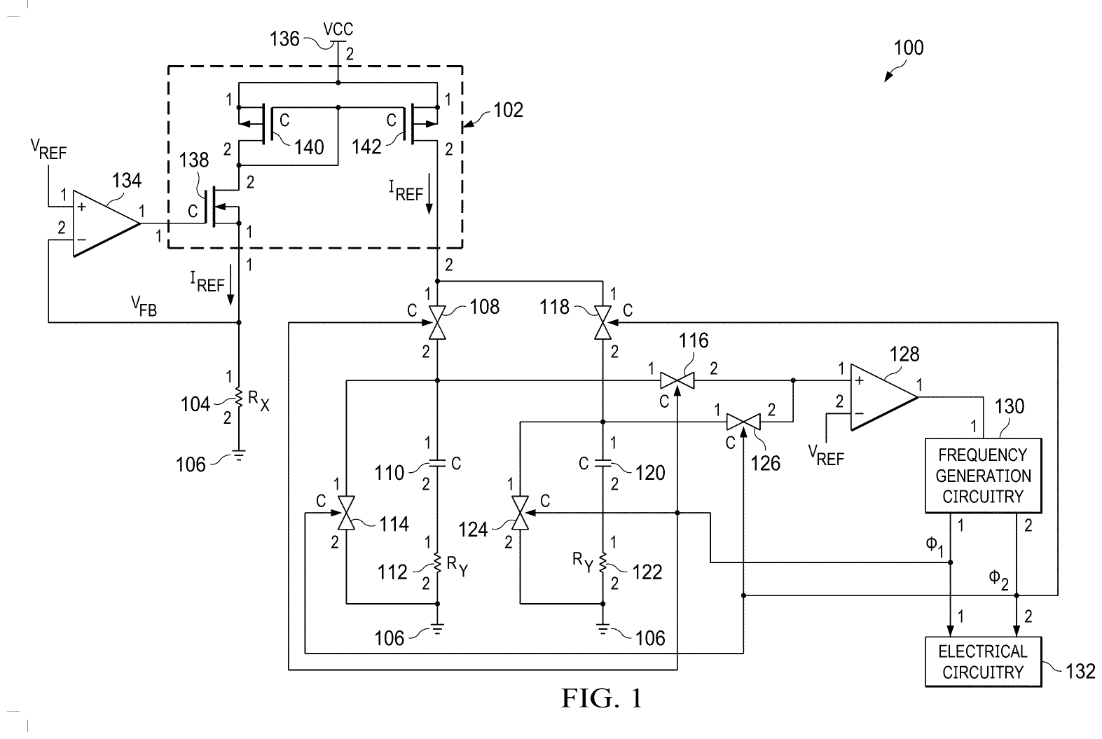

FIG. 1 is a schematic diagram of an example oscillator 100 that compensates for variation resulting from at least one electrical characteristic, according to an embodiment of the present disclosure. For example, the oscillator 100 of FIG. 1 compensates for variation resulting from at least sensitivity to package stress. In the example of FIG. 1, the oscillator 100 includes an example current mirror 102, an example first resistor 104, an example ground terminal 106, an example first switch 108, an example first capacitor 110, an example second resistor 112, an example second switch 114, an example third switch 116. Also, the oscillator 100 of FIG. 1 includes an example fourth switch 118, an example second capacitor 120, an example third resistor 122, an example fifth switch 124, and an example sixth switch 126.

In the illustrated example of FIG. 1, the oscillator 100 includes an example comparator 128, example frequency generation circuitry 130, example electrical circuitry 132, an example amplifier 134, and an example supply voltage terminal 136. Also, the current mirror 102 of FIG. 1 includes an example first transistor 138, an example second transistor 140, and an example third transistor 142. In the example of FIG. 1, the current mirror 102 has a first input terminal, a second input terminal, a first output terminal, and a second output terminal. Also, each of the first resistor 104, the second resistor 112, the third resistor 122, the first capacitor 110, and the second capacitor 120 has a first terminal and a second terminal.

In the illustrated example of FIG. 1, each of the first switch 108, the second switch 114, the third switch 116, the fourth switch 118, the fifth switch 124, the sixth switch 126, the first transistor 138, the second transistor 140, and the third transistor 142 has a control terminal, a first terminal, and a second terminal. In the example of FIG. 1, each of the comparator 128 and the amplifier 134 has a first input terminal, a second input terminal, and an output terminal. Also, the frequency generation circuitry 130 has an input terminal, a first output terminal, and a second output terminal. In the example of FIG. 1, the frequency generation circuitry 130 is in communication with the electrical circuitry 132 which has a first input terminal and a second input terminal.

In the illustrated example of FIG. 1, the first terminal of the first resistor 104 is coupled to the first output terminal of the current mirror 102 and the second input terminal of the amplifier 134. Also, the second terminal of the first resistor 104 is coupled to the ground terminal 106. In the example of FIG. 1, the control terminal of the first switch 108 is coupled to the first output terminal of the frequency generation circuitry 130, the first terminal of the first switch 108 is coupled to the second output terminal of the current mirror 102, and the second terminal of the first switch 108 is coupled to the first terminal of the first capacitor 110. In the example of FIG. 1, the first terminal of the first capacitor 110 is coupled to the second terminal of the first switch 108 and the second terminal of the first capacitor 110 is coupled to the first terminal of the second resistor 112.

In the illustrated example, the first terminal of the second resistor 112 is coupled to the second terminal of the first capacitor 110 and the second terminal of the second resistor 112 is coupled to the ground terminal 106. Also, the control terminal of the second switch 114 is coupled to the second output terminal of the frequency generation circuitry 130, the first terminal of the second switch 114 is coupled to the first terminal of the first capacitor 110, and the second terminal of the second switch 114 is coupled to the ground terminal 106. In the example of FIG. 1, the control terminal of the third switch 116 is coupled to the first output terminal of the frequency generation circuitry 130, the first terminal of the third switch 116 is coupled to the first terminal of the first capacitor 110, and the second terminal of the third switch 116 is coupled to the first input terminal of the comparator 128.

In the illustrated example of FIG. 1, the control terminal of the fourth switch 118 is coupled to the second output terminal of the frequency generation circuitry 130, the first terminal of the fourth switch 118 is coupled to the second output terminal of the current mirror 102, and the second terminal of the fourth switch 118 is coupled to the first terminal of the second capacitor 120. Also, the first terminal of the second capacitor 120 is coupled to the second terminal of the fourth switch 118 and the second terminal of the second capacitor 120 is coupled to the first terminal of the third resistor 122. In the example of FIG. 1, the first terminal of the third resistor 122 is coupled to the second terminal of the second capacitor 120 and the second terminal of the third resistor 122 is coupled to the ground terminal 106.

In the illustrated example of FIG. 1, the control terminal of the fifth switch 124 is coupled to the first output terminal of the frequency generation circuitry 130, the first terminal of the fifth switch 124 is coupled to the first terminal of the second capacitor 120, and the second terminal of the fifth switch 124 is coupled to the ground terminal 106. Also, the control terminal of the sixth switch 126 is coupled to the second output terminal of the frequency generation circuitry 130, the first terminal of the sixth switch 126 is coupled to the first terminal of the second capacitor 120, and the second terminal of the sixth switch 126 is coupled to the first input terminal of the comparator 128. In the example of FIG. 1, the first input terminal of the comparator 128 is coupled to the second terminal of the third switch 116 and the second terminal of the sixth switch 126, the second input terminal of the comparator 128 is coupled to a reference voltage terminal, and the output terminal of the comparator 128 is coupled to the input terminal of the frequency generation circuitry 130.

In the illustrated example of FIG. 1, the input terminal of the frequency generation circuitry 130 is coupled to the output terminal of the comparator 128. Also, the first output terminal of the frequency generation circuitry 130 is coupled to the control terminal of the first switch 108, the control terminal of the third switch 116, the control terminal of the fifth switch 124, and the first input terminal of the electrical circuitry 132. In the example of FIG. 1, the second output terminal of the frequency generation circuitry 130 is coupled to the control terminal of the second switch 114, the control terminal of the fourth switch 118, the control terminal of the sixth switch 126, and the second input terminal of the electrical circuitry 132. Also, the first input terminal of the electrical circuitry 132 is coupled to the first output terminal of the frequency generation circuitry 130 and the second input terminal of the electrical circuitry 132 is coupled to the second output terminal of the frequency generation circuitry 130.

In the illustrated example of FIG. 1, the first input terminal of the amplifier 134 is coupled to the reference voltage terminal, the second input terminal of the amplifier 134 is coupled to the first terminal of the first resistor 104 and the first output terminal of the current mirror 102, and the output terminal of the amplifier 134 is coupled to the control terminal of the first transistor 138. Also, the control terminal (e.g., a gate terminal) of the first transistor 138 is coupled to the output terminal of the amplifier 134, the first terminal (e.g., a source terminal) of the first transistor 138 is coupled to the first terminal of the first resistor 104 and the second input terminal of the amplifier 134, and the second terminal (e.g., a drain terminal) of the first transistor 138 is coupled to the second terminal of the second transistor 140. In the example of FIG. 1, the control terminal (e.g., a gate terminal) of the second transistor 140 is coupled to the second terminal of the second transistor 140 and the control terminal of the third transistor 142.

In the illustrated example of FIG. 1, the first terminal (e.g., a source terminal) of the second transistor 140 is coupled to the supply voltage terminal 136. Also, the second terminal (e.g., a drain terminal) of the second transistor 140 is coupled to the control terminal of the second transistor 140 and the second terminal of the first transistor 138. In the example of FIG. 1, the control terminal (e.g., a gate terminal) of the third transistor 142 is coupled to the control terminal of the second transistor 140 and the first terminal (e.g., a source terminal) of the third transistor 142 is coupled to the supply voltage terminal 136. Also, the second terminal (e.g., a drain terminal) of the third transistor 142 is coupled to the first terminal of the first switch 108 and the first terminal of the fourth switch 118.

In the illustrated example of FIG. 1, the first resistor 104 has a resistance of R_{X}. Also, the second resistor 112 and the third resistor 122 have a resistance of R_{Y}, although there may be variations in the real-world values of the resistances of the second resistor 112 and the third resistor 122. As such, the resistances of the second resistor 112 and the third resistor 122 may not be exactly the same. In the example of FIG. 1, the first capacitor 110 and the second capacitor 120 have a capacitance of C, although there may be variations in the real-world values of the capacitance of the first capacitor 110 and the second capacitor 120. As such, the capacitances of the first capacitor 110 and the second capacitor 120 may not be exactly the same.

As described above, the oscillator 100 compensates for sensitivity to package stress. The effective stress sensitivity of two resistors in series (or two capacitors in parallel) can be computed as illustrated in Equation 5 below.

$${SX}_{EFF} = \frac{{C}_{{R}_{X}} * S {X}_{{R}_{X}} + {C}_{{R}_{Y}} * S {X}_{{R}_{Y}}}{{C}_{{R}_{X}} + {C}_{{R}_{Y}}} \qquad Equation 5$$

In Equation 5, SX_{EFF} represents the effective stress sensitivity of a series combination of the first resistor 104 and at least one of the second resistor 112 or the third resistor 122, SX_{R}_{_{X}} represents the stress sensitivity of the first resistor 104, and SX_{R}_{_{Y}} represents the stress sensitivity of the second resistor 112 and the third resistor 122. Also, in Equation 5, C_{R}_{_{X}} and CRY are coefficients for the stress sensitivity of (1) the first resistor 104 and (2) the second resistor 112 and the third resistor 122, respectively. Table 1 below illustrates the sensitivity to stress of the first resistor 104, the second resistor 112, and the third resistor 122, according to an embodiment.

TABLE 1

| | Stress Sensitivity |
|---|---|
| Component | (%/100 Megapascals (MPa)) |
| R_{X} | −0.461 |
| R_{Y} | 0.12 |

As illustrated in Equation 6 below, the ratio between (1) the resistance of the first resistor 104 and (2) the resistance of the second resistor 112 and the third resistor 122 can be computed by solving Equation 5 for the coefficients C_{R}_{_{X}} and C_{R}_{_{Y}}.

$${R}_{X} : {R}_{Y} = {C}_{{R}_{X}} : {C}_{{R}_{Y}} \qquad Equation 6$$

For example, assuming a target effective stress sensitivity of zero and that C_{R}_{_{X}} equals one, Equation 5 can be solved for C_{R}_{_{Y}}. (e.g.,

$$0 = \frac{1 * ( - 0.461 ) + {C}_{{R}_{Y}} * ( 0.12 )}{1 + {C}_{{R}_{Y}}} \to {C}_{{R}_{Y}} \approx 3.84$$

). Under such assumptions, the ratio between (1) the resistance of the first resistor 104 and (2) the resistance of the second resistor 112 and the third resistor 122 is ˜1:3.84. As such, if the resistance of the first resistor 104 is one kiloohm (kΩ) (e.g., R_{X}=1 kΩ), then the resistance of the second resistor 112 and the third resistor 122 is 3.84 kΩ (e.g., R_{Y}=3.84 kΩ) to reduce the effective stress sensitivity of the series combination of the first resistor 104 and at least one of the second resistor 112 or the third resistor 122 (e.g.,

$${SX}_{EFF} = \frac{1 * ( - 0.461 ) + 3.84 * ( 0.12 )}{1 + 3.84} \approx 0$$

).

In the illustrated example of FIG. 1, the ratio between (1) the resistance of the first resistor 104 and (2) the resistance of the second resistor 112 and the third resistor 122 is 1:3.84 (R_{X}:R_{Y}=1:3.84). Also, in the example of FIG. 1, (1) the first resistor 104 is implemented on a first side of the current mirror 102 and (2) the second resistor 112 and the third resistor 122 are implemented on a second side of the current mirror 102, different than the first side. Equation 9 below illustrates how the first resistor 104 and at least one of the second resistor 112 or the third resistor 122 are linearly combined in the oscillator 100. Advantageously, by linearly combining the first resistor 104 with at least one of the second resistor 112 or the third resistor 122 in this manner, the oscillator 100 compensates for variance in the resistance of the first resistor 104 with respect to package stress.

For example, by implementing (1) the first resistor 104 on a first side of the current mirror 102 and (2) the second resistor 112 and the third resistor 122 on the other side of the current mirror 102, the variance of at least one of the second resistor 112 or the third resistor 122 to stress is subtracted from the variance of the first resistor 104 to stress. As such, the effective sensitivity of the oscillator 100 to stress is reduced. Equations 7-9 illustrate the resistance subtraction achieved by the oscillator 100 of FIG. 1.

In the illustrated example of FIG. 1, the current mirror 102 generates a reference current (I_{REF}) at the first output terminal of the current mirror 102. For example, the amplifier 134 controls the voltage at the control terminal of the first transistor 138 to operate the first transistor 138 as a current source. The amplifier 134 controls the first transistor 138 to generate the reference current (I_{REF}) as illustrated in Equation 7 below.

$${I}_{REF} = \frac{{V}_{REF}}{{R}_{X}} \qquad Equation 7$$

In the illustrated example of FIG. 1, the second transistor 140 and the third transistor 142 are structured to operate in a saturation region. In the example of FIG. 1, the current generated at the second output terminal of the current mirror 102 is dependent on the weight to length (W/L) ratio of the second transistor 140 and the W/L ratio of the third transistor 142. By matching the W/L ratio of the second transistor 140 to the W/L ratio of the third transistor 142, the current mirror 102 is structured to generate a current at the second output terminal that is equivalent to the reference current (I_{REF}), although there may be variations in the real-world values of the currents at the first output terminal and the second output terminal of the current mirror 102. As such, the currents at the first output terminal and the second output terminal of the current mirror 102 may not be exactly the same.

In the illustrated example of FIG. 1, a reference voltage (V_{REF}) at the reference voltage terminal can be expressed in terms of the reference current (I_{REF}), the resistance of at least one of the second resistor 112 or the third resistor 122, the capacitance of at least one of the first capacitor 110 or the second capacitor 120, and the period of the first signal, ϕ₁, and the second signal, ϕ₂, generated by the frequency generation circuitry 130, as illustrated in Equation 8 below. In Equation 8, T_{OSC} represents a period of a first signal, ϕ₁, and a second signal, ϕ₂ generated by the frequency generation circuitry 130.

$${V}_{REF} = {I}_{REF} * {R}_{Y} + \frac{0.5 * {T}_{OSC} * {I}_{REF}}{C} \qquad Equation 8$$

In the illustrated example of FIG. 1, the period, T_{OSC}, of the first signal, ϕ₁, and the second signal, ϕ₂, generated by the frequency generation circuitry 130 can be expressed in terms of the resistance of the first resistor 104, the resistance of the second resistor 112 and the third resistor 122, and the capacitance of the first capacitor 110 and the second capacitor 120 as illustrated in Equation 9 below. In Equation 9, the period, T_{OSC}, of the first signal, ϕ₁, and the second signal, ϕ₂, generated by the frequency generation circuitry 130 is the inverse of the frequency, f_{OSC}, of the first signal, ϕ₁, and the second signal, ϕ₂, generated by the frequency generation circuitry 130.

$${T}_{OSC} = \frac{1}{{f}_{OSC}} = 2 C * ( {R}_{X} - {R}_{Y} ) \qquad Equation 9$$

As described above, by implementing (1) the first resistor 104 on a first side of the current mirror 102 and (2) the second resistor 112 and the third resistor 122 on the other side of the current mirror 102, the effective sensitivity of the oscillator 100 to stress is reduced. For example, as the resistance of the first resistor 104 changes with respect to stress, a similar change occurs in the resistance of the second resistor 112 and the third resistor 122. As illustrated in Equation 9, because (1) the first resistor 104 is on a first side of the current mirror 102 and (2) the second resistor 112 and the third resistor 122 are on the other side of the current mirror 102, the resistance of the second resistor 112 and the third resistor 122 is subtracted from the resistance of the first resistor 104. Thus, the effective change in resistance of the oscillator 100 with respect to stress may be eliminated.

Also, by compensating for package stress as illustrated in FIG. 1, examples described herein may advantageously achieve circuit operation that is invariant to stress in a manner that consumes a relatively small amount of area on a semiconductor die. In some examples, to increase the variance of the frequency, f_{OSC}, of the first signal, ϕ₁, and the second signal, ϕ₂, generated by the frequency generation circuitry 130 to stress, the first resistor 104 can be implemented on the same side of the current mirror 102 as at least one of the second resistor 112 or the third resistor 122. For example, the first resistor 104 can be implemented in series with at least one of the second resistor 112 or the third resistor 122.

As such, the electrical circuitry 132, which operates based on the first signal, ϕ₁, and the second signal, ϕ₂, generated by the frequency generation circuitry 130, may be invariant to package stress. For example, the electrical circuitry 132 is a microcontroller clocked by the first signal, ϕ₁, and the second signal, ϕ₂, generated by the frequency generation circuitry 130. In some examples, the electrical circuitry 132 is a digital signal processor (DSP) clocked by the first signal, ϕ₁, and the second signal, ϕ₂, generated by the frequency generation circuitry 130.

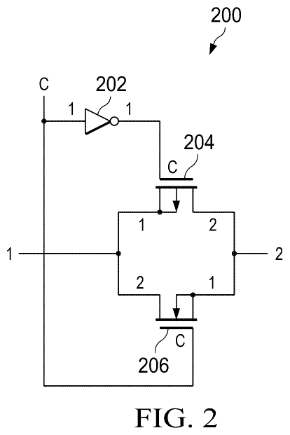

In the illustrated example of FIG. 1, the first switch 108, the second switch 114, the third switch 116, the fourth switch 118, the fifth switch 124, and the sixth switch 126 are implemented by complementary metal-oxide-semiconductor (CMOS) transmission gates. For example, FIG. 2 is a schematic diagram of an example implementation of a transmission gate 200. Also, the first transistor 138 is an N-channel metal-oxide semiconductor field-effect transistor (MOSFET). Alternatively, the first transistor 138 may be at least one of an N-channel field-effect transistor (FET), an N-channel insulated-gate bipolar transistor (IGBT), an N-channel junction field effect transistor (JFET), a negative-positive-negative (NPN) bipolar junction transistor (BJT), or, with slight modifications, a P-type equivalent device. In the example of FIG. 1, the second transistor 140 and the third transistor 142 are P-channel MOSFETs. Alternatively, the second transistor 140 and the third transistor 142 may be at least one of P-channel FETs, P-channel IGBTs, P-channel JFETs, positive-negative-positive (PNP) BJTs, or, with slight modifications, N-type equivalent devices. The first switch 108, the second switch 114, the third switch 116, the fourth switch 118, the fifth switch 124, the sixth switch 126, the first transistor 138, the second transistor 140, and the third transistor 142 may be at least one of depletion mode devices, drain-extended devices, enhancement mode devices, natural transistors, or other type of device structure transistors. Furthermore, the first switch 108, the second switch 114, the third switch 116, the fourth switch 118, the fifth switch 124, the sixth switch 126, the first transistor 138, the second transistor 140, and the third transistor 142 may be implemented in/over a silicon (Si) substrate, a silicon carbide (SiC) substrate, a gallium nitride (GaN) substrate, or a gallium arsenide (GaAs) substrate.

FIG. 2 is a schematic diagram of an example implementation of the transmission gate 200, which can be utilized to implement at least one of the first switch 108, the second switch 114, the third switch 116, the fourth switch 118, the fifth switch 124, or the sixth switch 126 of FIG. 1. The transmission gate 200 of FIG. 2 includes an example NOT gate 202, an example first switch 204, and an example second switch 206. In the example of FIG. 2, the NOT gate 202 has an input terminal and an output terminal. Also, each of the first switch 204 and the second switch 206 has a control terminal (e.g., a gate terminal), a first terminal (e.g., a source terminal), and a second terminal (e.g., a drain terminal).

In the illustrated example of FIG. 2, the input terminal of the NOT gate 202 is coupled to the control terminal of the second switch 206. Also, the output terminal of the NOT gate 202 is coupled to the control terminal of the first switch 204. In the example of FIG. 2, the control terminal of the first switch 204 is coupled to the output terminal of the NOT gate 202, the first terminal of the first switch 204 is coupled to the second terminal of the second switch 206, and the second terminal of the first switch 204 is coupled to the first terminal of the second switch 206.

In the illustrated example of FIG. 2, the control terminal of the second switch 206 is coupled to the input terminal of the NOT gate 202, the first terminal of the second switch 206 is coupled to the second terminal of the first switch 204, and the second terminal of the second switch 206 is coupled to the first terminal of the first switch 204. In the example of FIG. 2, the input terminal of the NOT gate 202 and the control terminal of the second switch 206 operate as a control terminal of the transmission gate 200. Also, the first terminal of the first switch 204 and the second terminal of the second switch 206 operate as a first terminal of the transmission gate 200. In the example of FIG. 2, the second terminal of the first switch 204 and the first terminal of the second switch 206 operate as a second terminal of the transmission gate 200.

In the illustrated example of FIG. 2, the first switch 204 is a P-channel MOSFET. Alternatively, the first switch 204 may be at least one of a P-channel FET, a P-channel IGBT, a P-channel JFET, a PNP BJT, or, with slight modifications, an N-type equivalent device. In the example of FIG. 2, the second switch 206 is an N-channel MOSFET. Alternatively, the second switch 206 may be at least one of an N-channel FET, an N-channel IGBT, an N-channel JFET, an NPN BJT, or, with slight modifications, a P-type equivalent device. The first switch 204 and the second switch 206 may be at least one of depletion mode devices, drain-extended devices, enhancement mode devices, natural transistors, or other type of device structure transistors. Furthermore, the first switch 204 and the second switch 206 may be implemented in/over an Si substrate, an SiC substrate, a GaN substrate, or a GaAs substrate.

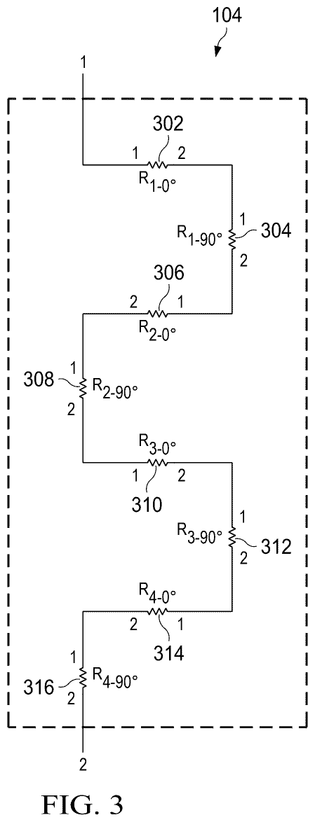

Returning to the example of FIG. 1, each of the first resistor 104, the second resistor 112, and the third resistor 122 may be implemented by two or more resistors that are oriented, from a layout perspective, at an angle (e.g., perpendicularly) with respect to one another to provide compensation for package stress regardless of whether the stress is applied laterally or longitudinally. For example, FIG. 3 is a schematic diagram of an example implementation of the first resistor 104 of FIG. 1 to compensate for lateral and longitudinal package stress, according to an embodiment of the present disclosure. In the example of FIG. 3, the first resistor 104 includes an example first resistor 302, an example second resistor 304, an example third resistor 306, an example fourth resistor 308, an example fifth resistor 310, an example sixth resistor 312, an example seventh resistor 314, and an example eighth resistor 316.

In the illustrated example of FIG. 3, each of the first resistor 302, the second resistor 304, the third resistor 306, the fourth resistor 308, the fifth resistor 310, the sixth resistor 312, the seventh resistor 314, and the eighth resistor 316 has a resistance that is one eighth of the resistance of the first resistor 104, although there may be variations in the real-world values of the resistances of the first resistor 302, the second resistor 304, the third resistor 306, the fourth resistor 308, the fifth resistor 310, the sixth resistor 312, the seventh resistor 314, and the eighth resistor 316. As such, the resistances of the first resistor 302, the second resistor 304, the third resistor 306, the fourth resistor 308, the fifth resistor 310, the sixth resistor 312, the seventh resistor 314, and the eighth resistor 316 may not be exactly the same. In the example of FIG. 3, each of the first resistor 302, the second resistor 304, the third resistor 306, the fourth resistor 308, the fifth resistor 310, the sixth resistor 312, the seventh resistor 314, and the eighth resistor 316 has a first terminal and a second terminal.

In the illustrated example of FIG. 3, the first terminal of the first resistor 302 operates as the first terminal of the first resistor 104 in FIG. 1. Also, the second terminal of the first resistor 302 is coupled to the first terminal of the second resistor 304. In the example of FIG. 3, the first terminal of the second resistor 304 is coupled to the second terminal of the first resistor 302 and the second terminal of the second resistor 304 is coupled to the first terminal of the third resistor 306. Also, the first terminal of the third resistor 306 is coupled to the second terminal of the second resistor 304 and the second terminal of the third resistor 306 is coupled to the first terminal of the fourth resistor 308. In the example of FIG. 3, the first terminal of the fourth resistor 308 is coupled to the second terminal of the third resistor 306 and the second terminal of the fourth resistor 308 is coupled to the first terminal of the fifth resistor 310.

In the illustrated example of FIG. 3, the first terminal of the fifth resistor 310 is coupled to the second terminal of the fourth resistor 308 and the second terminal of the fifth resistor 310 is coupled to the first terminal of the sixth resistor 312. Also, the first terminal of the sixth resistor 312 is coupled to the second terminal of the fifth resistor 310 and the second terminal of the sixth resistor 312 is coupled to the first terminal of the seventh resistor 314. In the example of FIG. 3, the first terminal of the seventh resistor 314 is coupled to the second terminal of the sixth resistor 312 and the second terminal of the seventh resistor 314 is coupled to the first terminal of the eighth resistor 316. Also, the first terminal of the eighth resistor 316 is coupled to the second terminal of the seventh resistor 314. In the example of FIG. 3, the second terminal of the eighth resistor 316 operates as the second terminal of the first resistor 104 in FIG. 1.

In the illustrated example of FIG. 3, the first resistor 302, the third resistor 306, the fifth resistor 310, and the seventh resistor 314 are parallel with one another in terms of physical orientation, although there may be variations in the real-world positions of the first resistor 302, the third resistor 306, the fifth resistor 310, and the seventh resistor 314. As such, the first resistor 302, the third resistor 306, the fifth resistor 310, and the seventh resistor 314 may not be exactly parallel. In the example of FIG. 3, the second resistor 304, the fourth resistor 308, the sixth resistor 312, and the eighth resistor 316 are parallel with one another in terms of physical orientation, although there may be variations in the real-world positions of the second resistor 304, the fourth resistor 308, the sixth resistor 312, and the eighth resistor 316. As such, the second resistor 304, the fourth resistor 308, the sixth resistor 312, and the eighth resistor 316 may not be exactly parallel.

In the illustrated example of FIG. 3, (1) the first resistor 302, the third resistor 306, the fifth resistor 310, and the seventh resistor 314 are perpendicular with respect to (2) the second resistor 304, the fourth resistor 308, the sixth resistor 312, and the eighth resistor 316. As such, regardless of whether stress is applied to the first resistor 104 laterally or longitudinally, the strain response of the first resistor 104 will be the same. The second resistor 112 and the third resistor 122 may be implemented similarly to the first resistor 104 of FIG. 3. As such, regardless of whether stress is applied to the oscillator 100 laterally or longitudinally, the effective sensitivity of the oscillator 100 to stress will be the same.

In examples described herein, any resistor (e.g., the second resistor 112, the third resistor 122, etc.) can be implemented as illustrated in FIG. 3. Furthermore, while an example manner of implementing the first resistor 104 is illustrated in the example of FIG. 3, one or more of the first resistor 302, the second resistor 304, the third resistor 306, the fourth resistor 308, the fifth resistor 310, the sixth resistor 312, the seventh resistor 314, or the eighth resistor 316 may be at least one of combined, divided, re-arranged, omitted, eliminated, or implemented in any other way. As such, there are many manners of implementing the first resistor 104. Also, any resistor described herein (e.g., the first resistor 104, the second resistor 112, the third resistor 122, etc.) can be implemented in any manner.

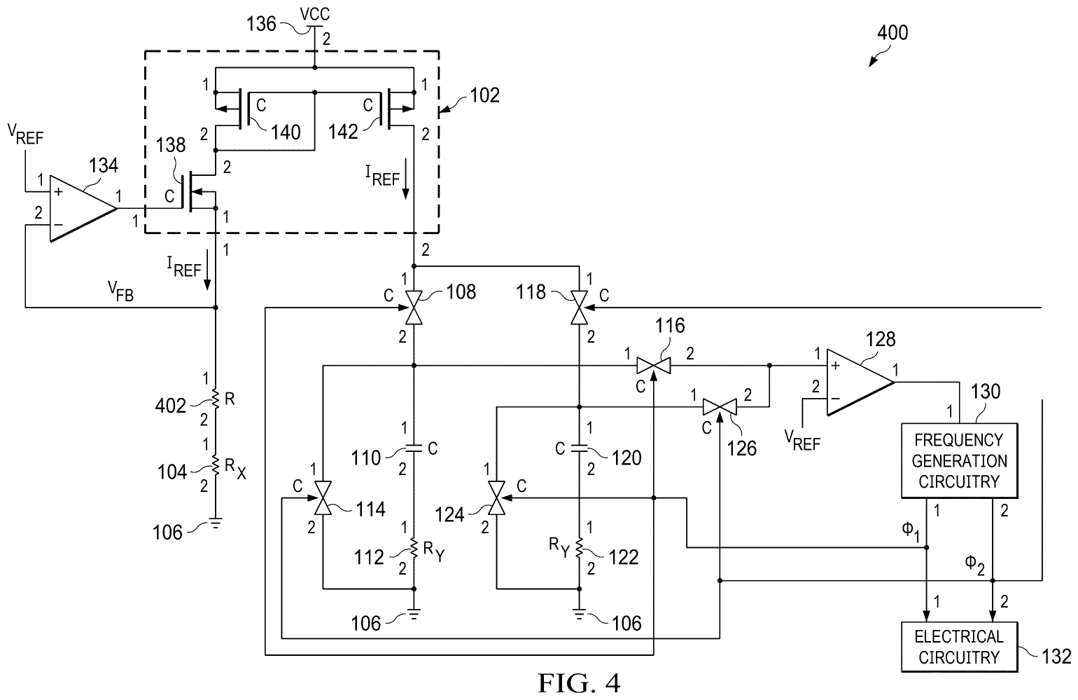

FIG. 4 is a schematic diagram of an example oscillator 400 that compensates for sensitivity to two electrical characteristics, according to an embodiment of the present disclosure. The oscillator 400 of FIG. 4 is implemented similarly to the oscillator 100 of FIG. 1 with the addition of an example resistor 402. In the example of FIG. 4, the resistor 402 has a first terminal coupled to the first output terminal of the current mirror 102 and the second input terminal of the amplifier 134. Also, the resistor 402 has a second terminal coupled to the first terminal of the first resistor 104. In the example of FIG. 4, the first terminal of the first resistor 104 is coupled to the second terminal of the resistor 402 and the second terminal of the first resistor 104 is coupled to the ground terminal 106. In the example of FIG. 4, the resistor 402 has a resistance of R.

As described above, the oscillator 400 compensates for sensitivity to two electrical characteristics. For example, the oscillator 400 compensates for the sensitivity of the first resistor 104 to package stress and compensates for the first-order temperature coefficient of resistivity of the first resistor 104. The effective stress sensitivity of three resistors in series (or three capacitors in parallel) can be computed as illustrated in Equation 10 below. Also, the effective first-order temperature coefficient of resistivity of three resistors in series (or three capacitors in parallel) can be computed as illustrated in Equation 11 below.

$${SX}_{EFF} = \frac{{C}_{R} * {SX}_{R} + {C}_{{R}_{X}} * {SX}_{{R}_{X}} + {C}_{{R}_{Y}} * {SX}_{{R}_{Y}}}{{C}_{R} + {C}_{{R}_{X}} + {C}_{{R}_{Y}}} \qquad Equation 10$$

$${α}_{EFF} = \frac{{C}_{R} * {α}_{R} + {C}_{{R}_{X}} * {α}_{{R}_{X}} + {C}_{{R}_{Y}} * {α}_{{R}_{Y}}}{{C}_{R} + {C}_{{R}_{X}} + {C}_{{R}_{Y}}} \qquad Equation 11$$

In Equation 10, SX_{EFF} represents the effective stress sensitivity of a series combination of the resistor 402, the first resistor 104, and at least one of the second resistor 112 or the third resistor 122, SX_{R} represents the stress sensitivity of the resistor 402, SX_{R}_{_{X}} represents the stress sensitivity of the first resistor 104, and SX_{R}_{_{Y}} represents the stress sensitivity of the second resistor 112 and the third resistor 122. In Equation 11, & EFF represents the effective first-order temperature coefficient of resistivity of a series combination of the resistor 402, the first resistor 104, and at least one of the second resistor 112 or the third resistor 122, α_{R} represents the first-order temperature coefficient of resistivity of the resistor 402, α_{R}_{_{X}} represents the first-order temperature coefficient of resistivity of the first resistor 104, and α_{R}_{_{Y}} represents the first-order temperature coefficient of resistivity of the second resistor 112 and the third resistor 122. Also, in Equations 10 and 11, C_{R}, C_{R}_{_{X}}, and C_{R}_{_{Y}} are coefficients for the stress sensitivity and first-order temperature coefficient of resistivity of (1) the resistor 402, (2) the first resistor 104, and (3) the second resistor 112 and the third resistor 122, respectively. Table 2 below illustrates the sensitivity to stress and the first-order temperature coefficient of resistivity of the resistor 402, the first resistor 104, the second resistor 112, and the third resistor 122, according to an embodiment.

TABLE 2

| | Stress Sensitivity | α |
|---|---|---|
| Component | (%/100 MPa) | (ppm/° C.) |
| R | 0.545 | −477 |
| R_{X} | −0.461 | 1490 |
| R_{Y} | 0.12 | 1447.14 |

As illustrated in Equation 12 below, the ratio between (1) the resistance of the resistor 402, (2) the resistance of the first resistor 104, and (3) the resistance of the second resistor 112 and the third resistor 122 can be computed by solving Equations 10 and 11 for the coefficients C_{R}, C_{R}_{_{X}}, and C_{R}_{_{Y}}.

$$R : {R}_{X} : {R}_{Y} = {C}_{R} : {C}_{{R}_{X}} : {C}_{{R}_{Y}} \qquad Equation 12$$

For example, assuming a target effective stress sensitivity of zero, a target effective first-order temperature coefficient of resistivity of zero, and that C_{R} equals one, Equations 10 and 11 can be solved for C_{R}_{_{X}} and C_{R}_{_{Y}}. (e.g.,

$$0 = \frac{1 * ( 0.545 ) + {C}_{{R}_{X}} * ( - 0.461 ) + {C}_{{R}_{Y}} * ( 0.12 )}{1 + {C}_{{R}_{X}} + {C}_{{R}_{Y}}} ,$$

$$0 = \frac{1 * ( - 477 ) + {C}_{{R}_{X}} * ( 1490 ) + {C}_{{R}_{Y}} * ( 1447.14 )}{1 + {C}_{{R}_{X}} + {C}_{{R}_{Y}}} \to {C}_{{R}_{X}} \approx 1 and$$

$${C}_{{R}_{Y}} \approx - 0.7$$

). Under such assumptions, the ratio between (1) the resistance of the resistor 402, (2) the resistance of the first resistor 104, and (3) the resistance of the second resistor 112 and the third resistor 122 is ˜1:1:−0.7. As such, if the resistance of the resistor 402 is 1 kΩ (e.g., R=1 kΩ), then the resistance of the first resistor 104 is 1 kΩ (e.g., R_{X}=1 kΩ) and the resistance of the second resistor 112 and the third resistor 122 is 700Ω (e.g., R_{Y}=700Ω) to reduce the effective stress sensitivity and the effective first-order temperature coefficient of resistivity of the series combination of the resistor 402, the first resistor 104, and at least one of the second resistor 112 or the third resistor 122 (e.g.,

$${SX}_{EFF} = \frac{1 * ( 0.545 ) + 1 * ( - 0.461 ) - 0.7 * ( 0.12 )}{1 + 1 - 0.7} = 0 ,$$

$${α}_{EFF} = \frac{1 * ( - 477 ) + 1 * ( 1490 ) - 0.7 * ( 1447.14 )}{1 + 1 - 0.7} \approx 0 \text{.002}$$

).

In the illustrated example of FIG. 4, the ratio between (1) the resistance of the resistor 402, (2) the resistance of the first resistor 104, and (3) the resistance of the second resistor 112 and the third resistor 122 is 1:1:−0.7 (R:R_{X}:R_{Y}=1:1:−0.7). To realize the negative ratio, the second resistor 112 and the third resistor 122 are implemented on the opposite side of the current mirror 102 from the resistor 402 and the first resistor 104. For example, (1) the resistor 402 and the first resistor 104 are implemented on a first side of the current mirror 102 and (2) the second resistor 112 and the third resistor 122 are implemented on a second side of the current mirror 102, different than the first side. Equation 14 below illustrates how the resistor 402, the first resistor 104, and at least one of the second resistor 112 or the third resistor 122 are linearly combined in the oscillator 400. Advantageously, by linearly combining the first resistor 104 with the resistor 402 and at least one of the second resistor 112 or the third resistor 122 in this manner, the oscillator 400 compensates for (1) the variance in the resistance of the first resistor 104 with respect to package stress and (2) the first-order temperature coefficient of resistivity of the first resistor 104.

For example, by implementing (1) the resistor 402 and the first resistor 104 on a first side of the current mirror 102 and (2) the second resistor 112 and the third resistor 122 on the other side of the current mirror 102, the variance of (1) at least one of the second resistor 112 or the third resistor 122 to stress is subtracted from the variance of (2) the resistor 402 and the first resistor 104 to stress. Also, by implementing (1) the resistor 402 and the first resistor 104 on a first side of the current mirror 102 and (2) the second resistor 112 and the third resistor 122 on the other side of the current mirror 102, the first-order variance of at least one of the second resistor 112 or the third resistor 122 to temperature is subtracted from the first-order variance of the resistor 402 and the first resistor 104 to temperature. As such, the effective sensitivity to stress and the effective first-order temperature coefficient of resistivity of the oscillator 400 are reduced.

Equations 13 and 14 illustrate the resistance subtraction achieved by the oscillator 400 of FIG. 4. For example, the current mirror 102 generates a reference current (I_{REF}) at the first output terminal of the current mirror 102. In the example of FIG. 4, the amplifier 134 controls the voltage at the control terminal of the first transistor 138 to operate the first transistor 138 as a current source. The amplifier 134 controls the first transistor 138 to generate the reference current (I_{REF}) as illustrated in Equation 13 below.

$${I}_{REF} = \frac{{V}_{REF}}{R + {R}_{X}} \qquad Equation 13$$

In the illustrated example of FIG. 4, the second transistor 140 and the third transistor 142 are structured to operate in a saturation region. In the example of FIG. 4, the current generated at the second output terminal of the current mirror 102 is dependent on the W/L ratio of the second transistor 140 and the W/L ratio of the third transistor 142. By matching the W/L ratio of the second transistor 140 to the W/L ratio of the third transistor 142, the current mirror 102 is structured to generate a current at the second output terminal that is equivalent to the reference current (I_{REF}), although there may be variations in the real-world values of the currents at the first output terminal and the second output terminal of the current mirror 102. As such, the currents at the first output terminal and the second output terminal of the current mirror 102 may not be exactly the same.

In the illustrated example of FIG. 4, the reference voltage (V_{REF}) at the reference voltage terminal can be expressed in terms of the reference current (I_{REF}), the resistance of at least one of the second resistor 112 or the third resistor 122, the capacitance of at least one of the first capacitor 110 or the second capacitor 120, and the period of the first signal, ϕ₁, and the second signal, ϕ₂, generated by the frequency generation circuitry 130, as illustrated in Equation 8 above. In the example of FIG. 4, the period, T_{OSC}, of the first signal, ϕ₁, and the second signal, ϕ₂, generated by the frequency generation circuitry 130 can be expressed in terms of the resistance of the resistor 402, the resistance of the first resistor 104, the resistance of the second resistor 112 and the third resistor 122, and the capacitance of the first capacitor 110 and the second capacitor 120 as illustrated in Equation 14 below. In Equation 14, the period, T_{OSC}, of the first signal, ϕ₁, and the second signal, ϕ₂, generated by the frequency generation circuitry 130 is the inverse of the frequency, f_{OSC}, of the first signal, ϕ₁, and the second signal, ϕ₂, generated by the frequency generation circuitry 130.

$${T}_{OSC} = \frac{1}{{f}_{OSC}} = 2 C * ( ( R + {R}_{X} ) - {R}_{Y} ) \qquad Equation 14$$

As described above, by implementing (1) the resistor 402 and the first resistor 104 on a first side of the current mirror 102 and (2) the second resistor 112 and the third resistor 122 on the other side of the current mirror 102, the effective sensitivity to stress and the effective first-order temperature coefficient of resistivity of the oscillator 400 is reduced. For example, as the resistance of the resistor 402 and the resistance of the first resistor 104 change with respect to stress and temperature (e.g., in terms of the first-order temperature coefficient of resistivity), a similar change occurs in the resistance of the second resistor 112 and the third resistor 122. As illustrated in Equation 14, because (1) the resistor 402 and the first resistor 104 are on a first side of the current mirror 102 and (2) the second resistor 112 and the third resistor 122 are on the other side of the current mirror 102, the resistance of the second resistor 112 and the third resistor 122 is subtracted from the resistance of the resistor 402 and the resistance of the first resistor 104. Thus, the effective change in resistance of the oscillator 400 with respect to stress and temperature (e.g., in terms of the first-order temperature coefficient of resistivity) may be eliminated.

Also, by compensating for package stress and first-order temperature variance as illustrated in FIG. 4, examples described herein may advantageously achieve circuit operation that is invariant to stress and temperature (e.g., in terms of the first-order temperature coefficient of resistivity) in a manner that consumes a relatively small amount of area on a semiconductor die. In some examples, to increase the variance of the frequency, f_{OSC}, of the first signal, ϕ₁, and the second signal, ϕ₂, generated by the frequency generation circuitry 130 to stress and temperature (e.g., in terms of the first-order temperature coefficient of resistivity), the resistor 402 and the first resistor 104 can be implemented on the same side of the current mirror 102 as at least one of the second resistor 112 or the third resistor 122. For example, the resistor 402 and the first resistor 104 can be implemented in series with at least one of the second resistor 112 or the third resistor 122.

As such, the electrical circuitry 132, which operates based on the first signal, ϕ₁, and the second signal, ϕ₂, generated by the frequency generation circuitry 130, is invariant to package stress and temperature (e.g., in terms of the first-order temperature coefficient of resistivity). For example, the electrical circuitry 132 is a microcontroller clocked by the first signal, ϕ₁, and the second signal, ϕ₂, generated by the frequency generation circuitry 130. In some examples, the electrical circuitry 132 is a digital signal processor (DSP) clocked by the first signal, ϕ₁, and the second signal, ϕ₂, generated by the frequency generation circuitry 130.

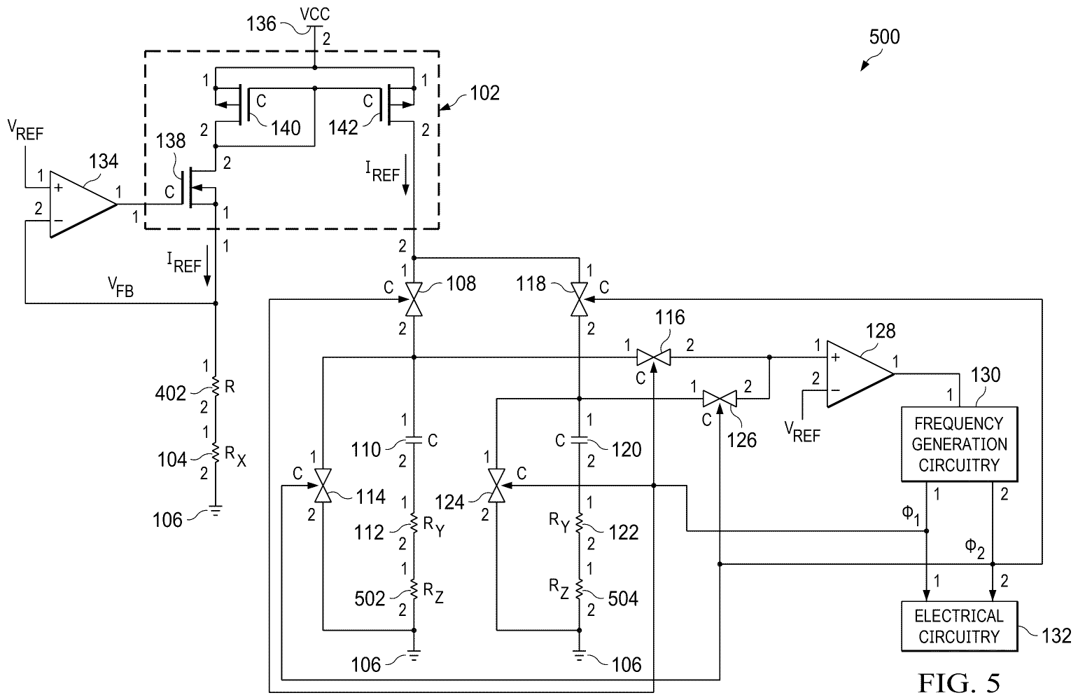

FIG. 5 is a schematic diagram of an example oscillator 500 that compensates for sensitivity to three electrical characteristics, according to an embodiment of the present disclosure. The oscillator 500 of FIG. 5 is implemented similarly to the oscillator 400 of FIG. 4 with the addition of an example first resistor 502 and an example second resistor 504. In the example of FIG. 5, each of the first resistor 502 and the second resistor 504 has a first terminal and a second terminal. Also, in the example of FIG. 5, the first resistor 502 and the second resistor 504 have a resistance of R_{Z}. although there may be variations in the real-world values of the resistances of the first resistor 502 and the second resistor 504. As such, the resistances of the first resistor 502 and the second resistor 504 may not be exactly the same.

In the illustrated example of FIG. 5, the first terminal of the first resistor 502 is coupled to the second terminal of the second resistor 112 and the second terminal of the first resistor 502 is coupled to the ground terminal 106. Also, the first terminal of the second resistor 112 is coupled to the second terminal of the first capacitor 110 and the second terminal of the second resistor 112 is coupled to the first terminal of first resistor 502. In the example of FIG. 5, the first terminal of the second resistor 504 is coupled to the second terminal of the third resistor 122 and the second terminal of the second resistor 504 is coupled to the ground terminal 106. Also, the first terminal of the third resistor 122 is coupled to the second terminal of the second capacitor 120 and the second terminal of the third resistor 122 is coupled to the first terminal of second resistor 504.

As described above, the oscillator 500 compensates for sensitivity to three electrical characteristics. For example, the oscillator 500 compensates for the sensitivity of the first resistor 104 to package stress, compensates for the first-order temperature coefficient of resistivity of the first resistor 104, and compensates for the second-order temperature coefficient of resistivity of the first resistor 104. The effective stress sensitivity of four resistors in series (or four capacitors in parallel) can be computed as illustrated in Equation 15 below. Also, the effective first-order temperature coefficient of resistivity of four resistors in series (or four capacitors in parallel) can be computed as illustrated in Equation 16 below and the effective second-order temperature coefficient of resistivity of four resistors in series (or four capacitors in parallel) can be computed as illustrated in Equation 17 below.

$${SX}_{EFF} = \frac{\begin{matrix}{C}_{R} * S {X}_{R} + {C}_{{R}_{X}} * S {X}_{{R}_{X}} + \\ {C}_{{R}_{Y}} * S {X}_{{R}_{Y}} + {C}_{{R}_{Z}} * S {X}_{{R}_{Z}}\end{matrix}}{{C}_{R} + {C}_{{R}_{X}} + {C}_{{R}_{Y}} + {C}_{{R}_{Z}}} \qquad Equation 15$$

$${α}_{EFF} = \frac{{C}_{R} * {α}_{R} + {C}_{{R}_{X}} * {α}_{{R}_{X}} + {C}_{{R}_{Y}} * {α}_{{R}_{Y}} + {C}_{{R}_{Z}} * {α}_{{R}_{Z}}}{{C}_{R} + {C}_{{R}_{X}} + {C}_{{R}_{Y}} + {C}_{{R}_{Z}}} \qquad Equation 16$$

$${β}_{EFF} = \frac{{C}_{R} * {β}_{R} + {C}_{{R}_{X}} * {β}_{{R}_{X}} + {C}_{{R}_{Y}} * {β}_{{R}_{Y}} + {C}_{{R}_{Z}} * {β}_{{R}_{Z}}}{{C}_{R} + {C}_{{R}_{X}} + {C}_{{R}_{Y}} + {C}_{{R}_{Z}}} \qquad Equation 17$$

In Equation 15, SX_{EFF} represents the effective stress sensitivity of a series combination of (1) the resistor 402, (2) the first resistor 104, (3) at least one of the second resistor 112 or the third resistor 122, and (4) at least one of the first resistor 502 or the second resistor 504. Also, in Equation 15, SX_{R} represents the stress sensitivity of the resistor 402 and SX_{R}_{_{X}} represents the stress sensitivity of the first resistor 104. In Equation 15, SX_{R}_{_{Y}} represents the stress sensitivity of the second resistor 112 and the third resistor 122 and SX_{R}_{_{Z}} represents the stress sensitivity of the first resistor 502 and the second resistor 504.

In Equation 16, EFF represents the effective first-order temperature coefficient of resistivity of a series combination of (1) the resistor 402, (2) the first resistor 104, (3) at least one of the second resistor 112 or the third resistor 122, and (4) at least one of the first resistor 502 or the second resistor 504. Also, in Equation 16, ap represents the first-order temperature coefficient of resistivity of the resistor 402 and @R_{Y} represents the first-order temperature coefficient of resistivity of the first resistor 104. In Equation 16, α_{R}_{_{Y}} represents the first-order temperature coefficient of resistivity of the second resistor 112 and the third resistor 122, and α_{R}_{_{Z}} represents the first-order temperature coefficient of resistivity of the first resistor 502 and the second resistor 504.

In Equation 17, β_{EFF} represents the effective second-order temperature coefficient of resistivity of a series combination of (1) the resistor 402, (2) the first resistor 104, (3) at least one of the second resistor 112 or the third resistor 122, and (4) at least one of the first resistor 502 or the second resistor 504. Also, in Equation 17, β_{R} represents the second-order temperature coefficient of resistivity of the resistor 402 and β_{R}_{_{X}} represents the second-order temperature coefficient of resistivity of the first resistor 104. In Equation 17, β_{R}_{_{Y}} represents the second-order temperature coefficient of resistivity of the second resistor 112 and the third resistor 122 and β_{R}_{_{Z}} represents the second-order temperature coefficient of resistivity of the first resistor 502 and the second resistor 504.

In Equations 15, 16, and 17, C_{R}, C_{R}_{_{X}}, C_{R}_{_{Y}}, and C_{R}_{_{Z}} are coefficients for the stress sensitivity, the first-order temperature coefficient of resistivity, and the second-order temperature coefficient of resistivity of (1) the resistor 402, (2) the first resistor 104, (3) the second resistor 112 and the third resistor 122, and (4) the first resistor 502 and the second resistor 504, respectively. Table 3 below illustrates the sensitivity to stress, the first-order temperature coefficient of resistivity, and the second-order temperature coefficient of resistivity of the resistor 402, the first resistor 104, the second resistor 112, the third resistor 122, the first resistor 502, and the second resistor 504.

TABLE 3

| | Stress Sensitivity | α | B |
|---|---|---|---|
| Component | (%/100 MPa) | (ppm/° C.) | (ppm/° C.²) |
| R | 0.545 | −477 | 1 |
| R_{X} | −0.461 | 1490 | 0.5 |
| R_{Y} | 0.12 | 1447.14 | 1 |
| R_{Z} | −0.01 | 0.01 | 0.8 |

As illustrated in Equation 18 below, the ratio between (1) the resistance of the resistor 402, (2) the resistance of the first resistor 104, (3) the resistance of the second resistor 112 and the third resistor 122, and (4) the resistance of the first resistor 502 and the second resistor 504 can be computed by solving Equations 15, 16, and 17 for the coefficients C_{R}, C_{R}_{_{X}}, C_{R}_{_{Y}}, and C_{R}_{_{Z}}.

$$R : {R}_{X} : {R}_{Y} : {R}_{Z} = {C}_{R} : {C}_{{R}_{X}} : {C}_{{R}_{Y}} : {C}_{{R}_{Z}} \qquad Equation 18$$

For example, assuming a target effective stress sensitivity of zero, a target effective first-order temperature coefficient of resistivity of zero, a target effective second-order temperature coefficient of resistivity of zero, and that C_{R} equals one, Equations 15, 16, and 17 can be solved for C_{R}_{_{X}}, C_{R}_{_{Y}}, and C_{R}_{_{Z}}. (e.g.,

$$0 = \frac{1 * ( 0.545 ) + {C}_{{R}_{X}} * ( - 0.461 ) + {C}_{{R}_{Y}} * ( 0.12 ) + {C}_{{R}_{Z}} * ( - 0.01 )}{1 + {C}_{{R}_{X}} + {C}_{{R}_{Y}} + {C}_{{R}_{Z}}} ,$$

$$0 = \frac{1 * ( - 477 ) + {C}_{{R}_{X}} * ( 1490 ) + {C}_{{R}_{Y}} * ( 1447.14 ) + {C}_{{R}_{Z}} * ( 0.01 )}{1 + {C}_{{R}_{X}} + {C}_{{R}_{Y}} + {C}_{{R}_{Z}}} ,$$

$$0 = \frac{1 * ( 1 ) + {C}_{{R}_{X}} * ( 0.5 ) + {C}_{{R}_{Y}} * ( 1 ) + {C}_{{R}_{Z}} * ( 0.08 )}{1 + {C}_{{R}_{X}} + {C}_{{R}_{Y}} + {C}_{{R}_{Z}}} \to {C}_{{R}_{X}} \approx 1 ,$$

$${C}_{{R}_{Y}} \approx - 0.7 , and {C}_{{R}_{Z}} \approx - 1$$

). Under such assumptions, the ratio between (1) the resistance of the resistor 402, (2) the resistance of the first resistor 104, (3) the resistance of the second resistor 112 and the third resistor 122, and (4) the resistance of the first resistor 502 and the second resistor 504 is ˜1:1:−0.7:−1. As such, if the resistance of the resistor 402 is 1 kΩ (e.g., R=1 kΩ), then the resistance of the first resistor 104 is 1 kΩ (e.g., R_{X}=1 kΩ), the resistance of the second resistor 112 and the third resistor 122 is 700Ω (e.g., R_{Y}=700Ω), and the resistance of the first resistor 502 and the second resistor 504 is 1 k (2 (e.g., R_{Z}=1 kΩ) to reduce the effective stress sensitivity, the effective first-order temperature coefficient of resistivity, and the effective second-order temperature coefficient of resistivity of the series combination of the resistor 402, the first resistor 104, at least one of the second resistor 112 or the third resistor 122, and at least one of the first resistor 502 or the second resistor 304 (e.g.,

$${SX}_{EFF} = \frac{1 * ( 0.545 ) + 1 * ( - 0.461 ) - 0.7 * ( 0.12 ) - 1 * ( - 0.01 )}{1 + 1 - 0.7 - 1} \approx 0.03 ,$$

$${α}_{EFF} = \frac{1 * ( - 477 ) + 1 * ( 1490 ) - 0.7 * ( 1447.14 ) - 1 * ( 0.01 )}{1 + 1 - 0.7 - 1} \approx - 0.026 ,$$

$${β}_{EFF} = \frac{1 * ( 1 ) + 1 * ( 0.5 ) - 0.7 * ( 1 ) - 1 * ( 0.8 )}{1 + 1 - 0.7 - 1} = 0$$

).

In the illustrated example of FIG. 5, the ratio between (1) the resistance of the resistor 402, (2) the resistance of the first resistor 104, (3) the resistance of the second resistor 112 and the third resistor 122, and (4) the resistance of the first resistor 502 and the second resistor 504 is 1:1:−0.7:−1 (R:R_{X}:R_{Y}:R_{Z}=1:1:−0.7:−1). To realize the negative ratios, the second resistor 112, the third resistor 122, the first resistor 502, and the second resistor 504 are implemented on the opposite side of the current mirror 102 from the resistor 402 and the first resistor 104. For example, (1) the resistor 402 and the first resistor 104 are implemented on a first side of the current mirror 102 and (2) the second resistor 112, the third resistor 122, the first resistor 502, and the second resistor 504 are implemented on a second side of the current mirror 102, different than the first side. Equation 19 below illustrates how the resistor 402, the first resistor 104, at least one of the second resistor 112 or the third resistor 122, and at least one of the first resistor 502 or the second resistor 504 are linearly combined in the oscillator 500. Advantageously, by linearly combining the first resistor 104 with the resistor 402, at least one of the second resistor 112 or the third resistor 122, and at least one of the first resistor 502 or the second resistor 504 in this manner, the oscillator 500 compensates for (1) the variance in the resistance of the first resistor 104 with respect to package stress (2) the first-order temperature coefficient of resistivity of the first resistor 104, and (3) the second-order temperature coefficient of resistivity of the first resistor 104.

For example, by implementing (1) the resistor 402 and the first resistor 104 on a first side of the current mirror 102 and (2) the second resistor 112, the third resistor 122, the first resistor 502, and the second resistor 504 on the other side of the current mirror 102, the variance of (1) at least one of the second resistor 112 or the third resistor 122 to stress and the variance of (2) at least one of the first resistor 502 or the second resistor 504 to stress is subtracted from the variance of (3) the resistor 402 and the first resistor 104 to stress. Also, by implementing (1) the resistor 402 and the first resistor 104 on a first side of the current mirror 102 and (2) the second resistor 112, the third resistor 122, the first resistor 502, and the second resistor 504 on the other side of the current mirror 102, the first-order and the second-order variance of (1) at least one of the second resistor 112 or the third resistor 122 to temperature and the first-order and the second-order variance of (2) at least one of the first resistor 502 or the second resistor 504 to temperature is subtracted from the first-order and the second-order variance of (3) the resistor 402 and the first resistor 104 to temperature. As such, the effective sensitivity to stress, the effective first-order temperature coefficient of resistivity, and the effective second-order temperature coefficient of resistivity of the oscillator 500 are reduced. Equation 19 below illustrates the resistance subtraction achieved by the oscillator 500 of FIG. 5.

In the illustrated example of FIG. 5, the current mirror 102 generates a reference current (I_{REF}) at the first output terminal of the current mirror 102 as illustrated in Equation 13 above. In the example of FIG. 5, the reference voltage (V_{REF}) at the reference voltage terminal can be expressed in terms of the reference current (I_{REF}) as illustrated in Equation 8 above. Also, in the example of FIG. 5, the period, T_{OSC}, of the first signal, ϕ₁, and the second signal, ϕ₂, generated by the frequency generation circuitry 130 can be expressed in terms of the resistance of the resistor 402, the resistance of the first resistor 104, the resistance of the second resistor 112 and the third resistor 122, the resistance of the first resistor 502 and the second resistor 504, and the capacitance of the first capacitor 110 and the second capacitor 120 as illustrated in Equation 19 below. In Equation 19, the period, T_{OSC}, of the first signal, ϕ₁, and the second signal, ϕ₂, generated by the frequency generation circuitry 130 is the inverse of the frequency, f_{OSC}, of the first signal, ϕ₁, and the second signal, ϕ₂, generated by the frequency generation circuitry 130.

$${T}_{OSC} = \frac{1}{{f}_{OSC}} = 2 C * ( ( R + {R}_{X} ) - {R}_{Y} - {R}_{Z} ) \qquad Equation 19$$

As described above, by implementing (1) the resistor 402 and the first resistor 104 on a first side of the current mirror 102 and (2) the second resistor 112, the third resistor 122, the first resistor 502, and the second resistor 504 on the other side of the current mirror 102, the effective sensitivity to stress, the effective first-order temperature coefficient of resistivity, and the effective second-order temperature coefficient of resistivity of the oscillator 500 may be reduced. For example, as the resistance of the resistor 402 and the resistance of the first resistor 104 change with respect to stress and temperature (e.g., in terms of the first-order and second-order temperature coefficients of resistivity), a similar change occurs in the resistance of the second resistor 112, the third resistor 122, the first resistor 502, and the second resistor 504. As illustrated in Equation 19, because (1) the resistor 402 and the first resistor 104 are on a first side of the current mirror 102 and (2) the second resistor 112, the third resistor 122, the first resistor 502, and the second resistor 504 are on the other side of the current mirror 102, the resistance of the second resistor 112, the third resistor 122, the first resistor 502, and the second resistor 504 is subtracted from the resistance of the resistor 402 and the resistance of the first resistor 104. Thus, the effective change in resistance of the oscillator 500 with respect to stress and temperature (e.g., in terms of the first-order and second-order temperature coefficient of resistivity) may be eliminated.

Also, by compensating for package stress, first-order temperature variance, and second-order temperature variance as illustrated in FIG. 5, examples described herein may advantageously achieve circuit operation that is invariant to stress and temperature (e.g., in terms of the first-order and second-order temperature coefficients of resistivity) in a manner that consumes a relatively small amount of area on a semiconductor die. In some examples, to increase the variance of the frequency, f_{OSC}, of the first signal, ϕ₁, and the second signal, ϕ₂, generated by the frequency generation circuitry 130 to stress and temperature (e.g., in terms of the first-order and second-order temperature coefficients of resistivity), the resistor 402 and the first resistor 104 can be implemented on the same side of the current mirror 102 as (1) at least one of the second resistor 112 or the third resistor 122 and (2) at least one of the first resistor 502 or the second resistor 504. For example, the resistor 402 and the first resistor 104 can be implemented in series with (1) at least one of the second resistor 112 or the third resistor 122 and (2) at least one of the first resistor 502 or the second resistor 504.

As such, the electrical circuitry 132, which operates based on the first signal, ϕ₁, and the second signal, ϕ₂, generated by the frequency generation circuitry 130, is invariant to package stress and temperature (e.g., in terms of the first-order and second-order temperature coefficients of resistivity). For example, the electrical circuitry 132 is a microcontroller clocked by the first signal, ϕ₁, and the second signal, ϕ₂, generated by the frequency generation circuitry 130. In some examples, the electrical circuitry 132 is a digital signal processor (DSP) clocked by the first signal, ϕ₁, and the second signal, ϕ₂, generated by the frequency generation circuitry 130.

In examples described herein, each of the first resistor 104 (e.g., the first resistor 302, the second resistor 304, the third resistor 306, the fourth resistor 308, the fifth resistor 310, the sixth resistor 312, the seventh resistor 314, and the eighth resistor 316) is implemented by an N-type polysilicon resistor, or, with slight modifications, a P-type equivalent device. Also, in examples described herein each of the second resistor 112, the third resistor 122, the first resistor 502, and the second resistor 504 is implemented by an N-type moat resistor, or, with slight modifications, a P-type equivalent device. For example, an N-type moat resistor is an N-type diffusion-based resistor that is surrounded by a P-type trench (e.g., a moat) that is situation in an N-type substrate to increase the isolation of the diffusion-based resistor. In examples described herein, the resistor 402 is implemented by a P-type moat resistor, or, with slight modifications, an N-type equivalent device. For example, a P-type moat resistor is a P-type diffusion-based resistor that is surrounded by an N-type trench (e.g., a moat) that is situated in a P-type substrate to increase the isolation of the diffusion-based resistor. Furthermore, the first resistor 104 (e.g., the first resistor 302, the second resistor 304, the third resistor 306, the fourth resistor 308, the fifth resistor 310, the sixth resistor 312, the seventh resistor 314, and the eighth resistor 316), the second resistor 112, the third resistor 122, the resistor 402, the first resistor 502, and the second resistor 504 may be implemented in/over an Si substrate, an SiC substrate, a GaN substrate, or a GaAs substrate. In examples described herein, any resistor can be implemented in a manner different than described above. For example, in a different process node based on resistor stress and temperature coefficient of resistivity characteristics, any of the first resistor 104 (e.g., the first resistor 302, the second resistor 304, the third resistor 306, the fourth resistor 308, the fifth resistor 310, the sixth resistor 312, the seventh resistor 314, and the eighth resistor 316), the second resistor 112, the third resistor 122, the resistor 402, the first resistor 502, or the second resistor 504 can be implemented in a manner different than described above.

A circuit or device that is described herein as including certain components may instead be adapted to be coupled to those components to form the described circuitry or device. For example, a structure described as including at least one of one or more semiconductor elements (such as transistors), one or more passive elements (such as at least one of resistors, capacitors, or inductors), or one or more sources (such as at least one of voltage sources or current sources) may instead include only the semiconductor elements within a single physical device (e.g., at least one of a semiconductor die or integrated circuit (IC) package) and may be adapted to be coupled to one or more at least some of the passive elements or at least some of the sources to form the described structure either at a time of manufacture or after a time of manufacture, for example, by at least one of an end-user or a third-party.

Circuits described herein may be reconfigurable to include the replaced components to provide functionality at least partially similar to functionality available prior to the component replacement. Components shown as resistors, unless otherwise stated, are generally representative of any one or more elements coupled at least one of in series or in parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, at least one of (a) some or all of the features illustrated as being external to the integrated circuit may be included in the integrated circuit or (b) some features illustrated as being internal to the integrated circuit may be incorporated outside of the integrated. As used herein, the term “integrated circuit” may be understood as one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. As used herein, “about” modifies its subject/value to recognize the potential presence of variations that occur in real world applications. For example, “about” may modify values that may not be exact due to at least one of manufacturing tolerances or other real-world imperfections. For example, unless otherwise stated, “about” preceding a value means+/−10 percent of the stated value, or, if the value is zero, a reasonable range of values around zero.

Modifications are possible in the described embodiments, and other embodiments are possible, within the scope of the claims.

From the foregoing, it will be appreciated that example systems, apparatus, articles of manufacture, and methods have been described that compensate for package stress variance or temperature variance. Described examples may advantageously reduce effective package stress sensitivity and/or variability with respect to temperature via a linear combination of resistors having different stress sensitivities and temperature coefficients of resistivity. For example, described examples include a weighted ratio between resistances of resistors combined in a circuit. To realize a positive ratio between resistance values, examples described herein may combine resistors in series. To realize a negative ratio between resistance values, examples described herein may combine resistors in a manner such that when computing a characteristic of operation of a circuit (e.g., frequency of operation), the current passing through a resistor having a negative coefficient is subtracted from the current passing through a resistor having a positive coefficient. For example, in a circuit including a current mirror, examples described herein include resistors having a positive coefficient in a first arm of the current mirror and resistors having a negative coefficient in a second arm of the current mirror different than the first arm.

As such, described examples may linearly combine resistors to reduce at least one of an effective stress sensitivity of a circuit, an effective first-order temperature coefficient of resistivity of the circuit, or an effective second-order temperature coefficient of resistivity of the circuit. Examples described herein can be utilized to adjust the variance of any electrical characteristic that has a linear relationship to circuit operation. By linearly combining resistors as described herein, examples described herein may consume a relatively small amount of area on a semiconductor die. Described systems, apparatus, articles of manufacture, and methods improve the efficiency of using a computing device by reducing the variability of circuit operation with respect to stress and temperature in a manner that consumes a small amount of area on a semiconductor die. Described systems, apparatus, articles of manufacture, and methods are directed to one or more improvement(s) in the operation of a machine such as at least one of a computer, other electronic device, or other mechanical device.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. An apparatus comprising:
a current mirror including a first output terminal and a second output terminal;
a first resistor including a first terminal coupled to the first output terminal of the current mirror and a second terminal coupled to a ground terminal;
a first switch including a control terminal, a first terminal, and a second terminal, the first terminal of the first switch coupled to the second output terminal of the current mirror;
a capacitor including a first terminal and a second terminal, the first terminal of the capacitor coupled to the second terminal of the first switch;
a second resistor including a first terminal coupled to the second terminal of the capacitor and a second terminal coupled to the ground terminal;
a second switch including a control terminal, a first terminal, and a second terminal, the first terminal of the second switch coupled to the first terminal of the capacitor, the second terminal of the second switch coupled to the ground terminal;
a third switch including a control terminal, a first terminal, and a second terminal, the first terminal of the third switch coupled to the first terminal of the capacitor;
a comparator including an input terminal and an output terminal, the input terminal of the comparator coupled to the second terminal of the third switch; and
circuitry including an input terminal coupled to the output terminal of the comparator, a first output terminal coupled to the control terminal of the first switch and the control terminal of the third switch, and a second output terminal coupled to the control terminal of the second switch.

2. The apparatus of claim 1, further including a third resistor including a first terminal coupled to the first output terminal of the current mirror and a second terminal coupled to the first terminal of the first resistor.

3. The apparatus of claim 1, further including a third resistor including a first terminal coupled to the second terminal of the second resistor and a second terminal coupled to the ground terminal.

4. The apparatus of claim 1, wherein at least one of the first switch, the second switch, or the third switch is a transmission gate.

5. The apparatus of claim 1, wherein the first resistor includes a third resistor and a fourth resistor, the third resistor oriented at an angle with respect to the fourth resistor to compensate for a stress applied to the first resistor at least one of laterally or longitudinally.

6. The apparatus of claim 1, wherein the capacitor is a first capacitor, and the apparatus further includes:
a fourth switch including a control terminal, a first terminal, and a second terminal, the control terminal of the fourth switch coupled to the second output terminal of the circuitry, the first terminal of the fourth switch coupled to the second output terminal of the current mirror;
a second capacitor including a first terminal and a second terminal, the first terminal of the second capacitor coupled to the second terminal of the fourth switch;
a third resistor including a first terminal coupled to the second terminal of the second capacitor and a second terminal coupled to the ground terminal;
a fifth switch including a control terminal coupled to the first output terminal of the circuitry, a first terminal coupled to the first terminal of the second capacitor, and a second terminal coupled to the ground terminal; and
a sixth switch including a control terminal coupled to the second output terminal of the circuitry, a first terminal coupled to the first terminal of the second capacitor, and a second terminal coupled to the input terminal of the comparator.

7. The apparatus of claim 6, further including a fourth resistor including a first terminal coupled to the first output terminal of the current mirror and a second terminal coupled to the first terminal of the first resistor.

8. The apparatus of claim 7, further including a fifth resistor including a first terminal coupled to the second terminal of the second resistor and a second terminal coupled to the ground terminal.

9. The apparatus of claim 8, further including a sixth resistor including a first terminal coupled to the second terminal of the third resistor and a second terminal coupled to the ground terminal.

10. The apparatus of claim 1, wherein the first resistor includes an N-type polysilicon resistor.

11. The apparatus of claim 1, wherein the input terminal of the comparator is a first input terminal, and the comparator has a second input terminal coupled to a reference voltage.

12. An oscillator comprising:
a current mirror including a first output terminal and a second output terminal;
a first resistor including a first terminal and a second terminal, the first terminal of the first resistor coupled to the first output terminal of the current mirror;
a second resistor including a first terminal coupled to the second terminal of the first resistor and a second terminal coupled to a ground terminal;
a first switch including a control terminal, a first terminal, and a second terminal, the first terminal of the first switch coupled to the second output terminal of the current mirror;
a capacitor including a first terminal and a second terminal, the first terminal of the capacitor coupled to the second terminal of the first switch;
a third resistor including a first terminal coupled to the second terminal of the capacitor and a second terminal coupled to the ground terminal;
a second switch including a control terminal, a first terminal, and a second terminal, the first terminal of the second switch coupled to the first terminal of the capacitor, the second terminal of the second switch coupled to the ground terminal;
a third switch including a control terminal, a first terminal, and a second terminal, the first terminal of the third switch coupled to the first terminal of the capacitor;
a comparator including an input terminal and an output terminal, the input terminal of the comparator coupled to the second terminal of the third switch; and
circuitry including an input terminal coupled to the output terminal of the comparator, a first output terminal coupled to the control terminal of the first switch and the control terminal of the third switch, and a second output terminal coupled to the control terminal of the second switch.

13. The oscillator of claim 12, wherein at least one of the first switch, the second switch, or the third switch is a transmission gate.

14. The oscillator of claim 12, wherein the second resistor includes a fourth resistor and a fifth resistor, the fourth resistor oriented at an angle with respect to the fifth resistor to compensate for a stress applied to the second resistor at least one of laterally or longitudinally.

15. The oscillator of claim 12, wherein the capacitor is a first capacitor, and the oscillator further includes:
a fourth switch including a control terminal, a first terminal, and a second terminal, the control terminal of the fourth switch coupled to the second output terminal of the circuitry, the first terminal of the fourth switch coupled to the second output terminal of the current mirror;
a second capacitor including a first terminal and a second terminal, the first terminal of the second capacitor coupled to the second terminal of the fourth switch;
a fourth resistor including a first terminal coupled to the second terminal of the second capacitor and a second terminal coupled to the ground terminal;
a fifth switch including a control terminal coupled to the first output terminal of the circuitry, a first terminal coupled to the first terminal of the second capacitor, and a second terminal coupled to the ground terminal; and
a sixth switch including a control terminal coupled to the second output terminal of the circuitry, a first terminal coupled to the first terminal of the second capacitor, and a second terminal coupled to the input terminal of the comparator.

16. The oscillator of claim 12, wherein the second resistor includes an N-type polysilicon resistor.

17. An integrated circuit comprising:
a current mirror including a first output terminal and a second output terminal;
a first resistor including a first terminal and a second terminal, the first terminal of the first resistor coupled to the first output terminal of the current mirror;
a second resistor including a first terminal coupled to the second terminal of the first resistor and a second terminal coupled to a ground terminal;
a first switch including a control terminal, a first terminal, and a second terminal, the first terminal of the first switch coupled to the second output terminal of the current mirror;
a first capacitor including a first terminal and a second terminal, the first terminal of the first capacitor coupled to the second terminal of the first switch;
a third resistor including a first terminal and a second terminal, the first terminal of the third resistor coupled to the second terminal of the first capacitor;
a fourth resistor including a first terminal coupled to the second terminal of the third resistor and a second terminal coupled to the ground terminal;
a second switch including a control terminal, a first terminal, and a second terminal, the first terminal of the second switch coupled to the first terminal of the first capacitor, the second terminal of the second switch coupled to the ground terminal;
a third switch including a control terminal, a first terminal, and a second terminal, the first terminal of the third switch coupled to the first terminal of the first capacitor;
a fourth switch including a control terminal, a first terminal, and a second terminal, the first terminal of the fourth switch coupled to the second output terminal of the current mirror;
a second capacitor including a first terminal and a second terminal, the first terminal of the second capacitor coupled to the second terminal of the fourth switch;
a fifth resistor including a first terminal and a second terminal, the first terminal of the fifth resistor coupled to the second terminal of the second capacitor;
a sixth resistor including a first terminal coupled to the second terminal of the fifth resistor and a second terminal coupled to the ground terminal;
a fifth switch including a control terminal, a first terminal, and a second terminal, the first terminal of the fifth switch coupled to the first terminal of the second capacitor, the second terminal of the fifth switch coupled to the ground terminal;
a sixth switch including a control terminal, a first terminal, and a second terminal, the first terminal of the sixth switch coupled to the first terminal of the second capacitor;
a comparator including an input terminal and an output terminal, the input terminal of the comparator coupled to the second terminal of the third switch and the second terminal of the sixth switch; and
circuitry including:
an input terminal coupled to the output terminal of the comparator;
a first output terminal coupled to the control terminal of the first switch, the control terminal of the third switch, and the control terminal of fifth switch; and
a second output terminal coupled to the control terminal of the second switch, the control terminal of the fourth switch, and the control terminal of the sixth switch.

18. The integrated circuit of claim 17, wherein at least one of the first switch, the second switch, the third switch, the fourth switch, the fifth switch, or the sixth switch is a transmission gate.

19. The integrated circuit of claim 17, wherein the second resistor includes a seventh resistor and an eighth resistor, the seventh resistor oriented at an angle with respect to the eighth resistor to compensate for a stress applied to the second resistor at least one of laterally or longitudinally.

20. The integrated circuit of claim 17, wherein the second resistor includes an N-type polysilicon resistor.
